(19) United States
(12) Patent Application Publication
(10) Pub. No.: US 2008/0063855 A1
(43) Pub. Date: Mar. 13, 2008

(54) SEMICONDUCTOR THIN FILMS FORMED FROM GROUP IV NANOPARTICLES

(76) Inventors: Maxim Kelman, Mountain View, CA (US); Pingrong Yu, Sunnyvale, CA (US); Manikandan Jayaraman, Santa Clara, CA (US); Dmitry Poplavskyy, San Jose, CA (US); David Jurbergs, Austin, TX (US); Francesco Lemmi, Santa Clara, CA (US); Homer Antoniadis, Mountain View, CA (US)

Correspondence Address: FOLEY & LARDNER LLP, 150 EAST GILMAN STREET, P.O. BOX 1497, MADISON, WI, 53701-1497, US

(21) Appl. No.: 11/851,004

(22) Filed: Sep. 6, 2007

Related U.S. Application Data
(60) Provisional application No. 60/842,818, filed on Sep. 7, 2006.

(51) Int. Cl. B32B 3/26; H01L 21/20

(52) U.S. Cl. 428/305.5; 438/502; 257/E21.09

(57) ABSTRACT

Native Group IV semiconductor thin films formed from coating substrates using formulations of Group IV nanoparticles are described. Such native Group IV semiconductor thin films leverage the vast historical knowledge of Group IV semiconductor materials and at the same time exploit the advantages of Group IV semiconductor nanoparticles for producing novel thin films which may be readily integrated into a number of devices.

### CROSS REFERENCE TO RELATED APPLICATIONS

The present application claims priority to U.S. Provisional Patent Application No. 60/842,818 filed Sep. 7, 2006. The contents of this provisional patent application are incorporated herein by reference in their entirety.

### FIELD

This disclosure relates to native semiconductor thin films formed from Group IV nanoparticle materials.

### BACKGROUND

The Group IV semiconductor materials enjoy wide acceptance as the materials of choice in a range devices in numerous markets such as communications, computation, and energy. Currently, particular interest is aimed in the art at improvements in semiconductor thin film technologies due to the widely recognized disadvantages of the current chemical vapor deposition (CVD) technologies.

In that regard, with the emergence of nanotechnology, there is in general growing interest in leveraging the advantages of these new materials in order to produce low-cost devices with designed functionality using high volume manufacturing on nontraditional substrates. It is therefore desirable to leverage the knowledge of Group IV semiconductor materials and at the same time exploit the advantages of Group IV semiconductor nanoparticles for producing novel thin films which may be readily integrated into a number of devices. Particularly, Group IV nanoparticles in the range of between about 1.0 nm to about 100.0 nm may exhibit a number of unique electronic, magnetic, catalytic, physical, optoelectronic, and optical properties due to quantum confinement and surface energy effects.

With respect to thin films compositions utilizing nanoparticles, U.S. Pat. No. 6,878,871 describes photovoltaic devices having thin layer structures that include inorganic nanostructures, optionally dispersed in a conductive polymer binder. Similarly, U.S. Patent Application Publication No. 2003/0226498 describes semiconductor nanocrystal/conjugated polymer thin films, and U.S. Patent Application Publication No. 2004/0126582 describes materials comprising semiconductor particles embedded in an inorganic or organic matrix. Notably, these references focus on the use of Group II-VI or III-V nanostructures in thin layer structures, rather than thin films formed from Group IV nanostructures.

An account of nanocrystalline silicon particles of about 30 nm in diameter, and formulated in a solvent-binder carrier is given in International Patent Application No. WO2004IB00221. The nanoparticles were mixed with organic binders such as polystyrene in solvents such as chloroform to produce semiconductor inks that were printed on bond paper without further processing. In U.S. Patent Application Publication No. 2006/0154036, composite sintered thin films of Group IV nanoparticles and hydrogenated amorphous Group IV materials are discussed. The Group IV nanoparticles are in the range 0.1 to 10 nm, in which the nanoparticles were passivated, typically using an organic passivation layer. In order to fabricate thin films from these passivated particles, the processing was performed at 400° C., where nanoparticles below 10 nm are used to lower the processing temperature. In both examples, significant amounts of organic materials are present in the Group IV thin film layers, and the composites formed are substantially different than the well-accepted native Group IV semiconductor thin films.

U.S. Pat. No. 5,576,248 describes Group IV semiconductor thin films formed from nanocrystalline silicon and germanium of 1 nm to 100 nm in diameter, where the film thickness is not more than three to four particles deep, yielding film thickness of about 2.5 nm to about 20 nm. For many electronic and photoelectronic applications, Group IV semiconductor thin films of about 150 nm to 3 microns are desirable.

Therefore, there is a need in the art for native Group IV semiconductor thin films of about 150 nm to 3 microns in thickness fabricated from Group IV semiconductor nanoparticles, which thin films are readily made using high volume processing methods.

### BRIEF DESCRIPTION OF THE DRAWINGS

FIG. 1 is a flow chart that depicts processing steps for the formation of embodiments of Group IV semiconductor thin films.

FIG. 2 is a schematic which depicts the formation of embodiments of Group IV semiconductor thin films from a porous compact film in an inert environment.

FIGS. 3A and 3B are scanning electron micrographs (SEMs) of silicon nanoparticle thin films comparing thin films formed from different deposition methods.

FIGS. 4A and 4B are SEM side views of an embodiment of a silicon nanoparticle thin film before (4A) and after (4B) thin film fabrication.

FIG. 5 is a graph showing the comparison of X-ray diffraction (XRD) data for an embodiment of a sintered thin film in comparison to the nanoparticle starting material.

FIG. 6 is an SEM side view of another embodiment of a silicon nanoparticle thin film.

FIG. 7 is a graph showing the characteristic current versus voltage responses for different embodiments of silicon nanoparticle thin films.

FIG. 8 is a side view of a silicon nanoparticle thin film which has been processed using pressure.

FIGS. 9A and 9B are SEM plan views of germanium films before (FIG. 9A) and after (FIG. 9B) thin film fabrication.

### DETAILED DESCRIPTION

What is disclosed herein are embodiments of native Group IV semiconductor thin films formed from coating substrates using dispersions of Group IV nanoparticles, methods for producing such Group IV semiconductor thin films, as well as embodiments of compositions of Group IV semiconductor nanoparticles, and methods for formulating the same.

For the purposes of this disclosure and unless otherwise specified, “a” or “an” means “one or more.” All patents, applications, references and publications cited herein are incorporated by reference in their entirety to the same extent as if they were individually incorporated by reference.

The materials, methods, and compositions evolved from the inventors' observations that by keeping embodiments of the Group IV semiconductor nanoparticles in an inert environment from the moment they are formed through the formation of Group IV semiconductor thin films, that embodiments of the thin films so produced have properties characteristic of bulk semiconductor materials. As will be discussed in more detail below, such properties include, but are not limited by, electrical, spectral absorbance, and photoconductive thin film properties.

As used herein, the term “Group IV semiconductor nanoparticle” generally refers to Group IV semiconductor particles having an average diameter between about 1.0 nm to 100.0 nm and may, in some instances, include elongated particle shapes, such as nanowires, or irregular shapes, in addition to more regular shapes, such as spherical, hexagonal, and cubic nanoparticles. Additionally, the nanoparticles may be single-crystalline, polycrystalline, or amorphous in nature. A plurality of nanoparticles may include nanoparticles of a single type of crystallinity or may consist of a range or mixture of crystallinity (i.e., some particles crystalline, others amorphous).

In that regard, Group IV semiconductor nanoparticles have an intermediate size between individual atoms and macroscopic bulk solids. In some embodiments, Group IV semiconductor nanoparticles have a size on the order of the Bohr exciton radius (e.g., 4.9 nm), or the de Broglie wavelength, which allows individual Group IV semiconductor nanoparticles to trap individual or discrete numbers of charge carriers, either electrons or holes, or excitons, within the particle. The Group IV semiconductor nanoparticles may exhibit a number of unique electronic, magnetic, catalytic, physical, optoelectronic and optical properties due to quantum confinement and surface energy effects. For example, Group IV semiconductor nanoparticles exhibit luminescence effects that are significantly greater than, as well as melting of nanoparticles substantially lower than the complementary bulk Group IV materials. These unique effects vary with properties such as size and composition of the nanoparticles. For example, and as will be discussed in more detail below, the melting of germanium nanoparticles is significantly lower than the melting of silicon nanoparticles of comparable size.

It is contemplated that only Group IV semiconductor nanoparticles of suitable quality be used as starting materials for embodiments of the thin film compositions disclosed herein. Particle quality includes, but is not limited by, particle morphology, average size, size distribution, and purity. For embodiments of disclosed Group IV semiconductor particles, suitable nanoparticle materials useful as starting materials have distinct particle morphology, with low incidence of particle clumping, agglomeration, or fusion. As was mentioned previously, the properties that are imparted for Group IV semiconductor nanoparticles are related closely to the particle size. In that regard, for many applications, a monodisperse population of particles of specific diameters is also indicated. Finally, with respect to purity, the Group IV semiconductor nanoparticles must be substantially oxygen free.

In consideration of the relationship between particle size and unique properties of Group IV semiconductor nanoparticles, for nanoparticles of about 1.0 nm to about 10 nm, at the lower end of what is defined as colloidal, the surface area to volume ratio, is a hundred to a thousand times greater than for colloids 1.0 micron in size at the other end of the range of what is defined as colloidal. These high surface areas, as well as other factors, such as, for example, the strain of the Group IV atoms at curved surfaces, are conjectured to account for the inventors' observations of the extraordinary reactivity of these Group IV semiconductor nanoparticles.

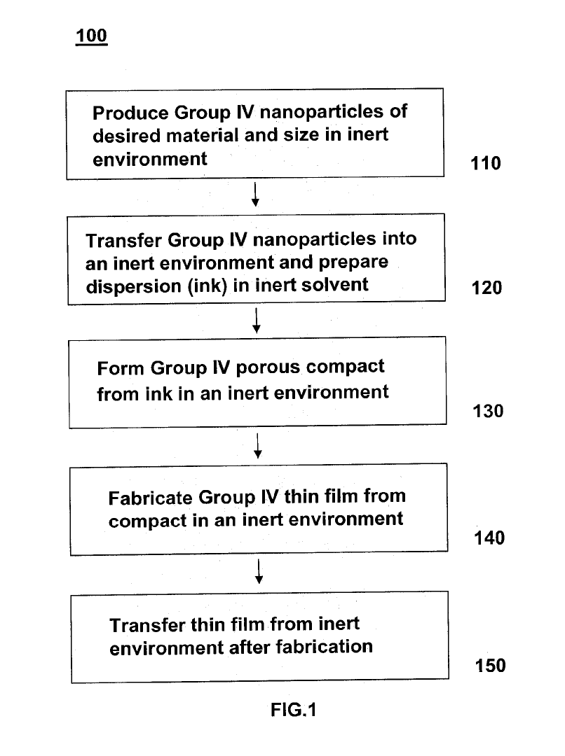

As a result of these observations, as shown in step 110 of process flow chart 100 shown in FIG. 1, scrupulous care has been taken to produce hydrogen terminated Group IV semiconductor nanoparticles fabricated in an inert environment, and as such, substantially free of oxygen. It is known that for bulk materials, substantially free of oxygen falls in the range of about 10¹⁷ to 10¹⁹ oxygen atoms per cubic centimeter of Group IV semiconductor material. In comparison, for example, for semiconductor grade silicon, there are 5.0×10²² silicon atoms per cubic centimeter, while for semiconductor grade germanium there are 4.4×10²² germanium atoms per cubic centimeter. In that regard, oxygen can be no greater than about 2 parts per million to about 200 parts per thousand as a contaminant in Group IV semiconductor materials. Therefore, it is indicative that embodiments of Group IV semiconductor thin films disclosed herein are substantially oxygen free if they have comparable electrical and photoconductive properties versus the response of bulk Group IV semiconductor materials.

Though as previously discussed a substantially oxygen free environment is indicated in the fabrication and handling of the Group IV semiconductor nanoparticles, as used herein, “inert” is not limited to only substantially oxygen-free. It is recognized that other fluids (i.e., gases, solvents, and solutions) may react in such a way that they negatively affect the electrical and photoelectrical properties of Group IV semiconductor nanoparticles. Accordingly, an inert environment for the purposes of this disclosure is an environment in which there are no fluids (gases, solvents, and solutions) that react in such a way that they would negatively affect the electrical and photoelectrical properties of the Group IV semiconductor nanoparticles. Similarly, an inert gas is any gas that does not react with the Group IV semiconductor nanoparticles in such a way that it negatively affects the electrical and photoelectrical properties of the Group IV semiconductor nanoparticles. Likewise, an inert solvent is any solvent that does not react with the Group IV semiconductor nanoparticles in such a way that it negatively affects the electrical and photoelectrical properties of the Group IV semiconductor nanoparticles. Finally, an inert solution is mixture of two or more substances that does not react with the Group IV semiconductor nanoparticles in such a way that it negatively affects the electrical and photoelectrical properties of the Group IV semiconductor nanoparticles.

The Group IV semiconductor nanoparticles may be made according to any suitable method, several of which are known, provided they are initially formed in an environment that is substantially inert. Examples of inert gases that may be used to provide an inert environment include nitrogen and the rare gases, such as argon. As used herein, the terms “substantially oxygen free” in reference to environments, solvents, or solutions refer to environments, solvents, or solutions wherein the oxygen content has been substantially reduced to produce Group IV semiconductor thin films having no more than 10¹⁷ to 10¹⁹ oxygen per cubic centimeter of Group IV semiconductor thin film.

In some instances a substantially oxygen-free conditions will contain no more than about 10 ppm oxygen. This includes embodiments where the substantially oxygen-free conditions contain no more than about 1 ppm oxygen and further includes embodiments where the substantially oxygen-free conditions contain no more than about 100 ppb oxygen. For example, if the Group IV semiconductor nanoparticles are made in a solvent phase, they should be removed from solvent and further processed under vacuum or an inert, substantially oxygen-free atmosphere. In another example, the solvent in which the Group IV semiconductor nanoparticles are made may be an anhydrous, deoxygenated liquid held under vacuum or inert gas to minimize the dissolved oxygen content in the liquid. Alternatively, the Group IV semiconductor nanoparticles may be made in the gas phase or in a plasma reactor in an inert, substantially oxygen-free atmosphere.

Examples of methods for making Group IV semiconductor nanoparticles include plasma aerosol synthesis, gas-phase laser pyrolysis, chemical or electrochemical etching from larger Group IV semiconductor particles, reactive sputtering, sol-gel techniques, SiO₂ implantation, self-assembly, thermal vaporization, synthesis from inverse micelles, and laser ablation/immobilization on self-assembled monolayers.

When the Group IV semiconductor nanoparticles are made by etching larger nanoparticles to a desired size, the nanoparticles are considered to be “initially formed” once the etching process is completed. Descriptions of etching may be found in references such as Swihart et al., U.S. Patent Application Publication No. 2004/0229447, filed on Nov. 8, 2004. In the preparation of such descriptions for etching, there is no disclosure for maintaining the Group IV semiconductor materials in an inert, substantially oxygen-free environment. When preparing etched Group IV semiconductor nanoparticles as starting material for embodiments of the disclosed passivated Group IV semiconductor nanoparticles, subsequent to the etching step done under oxidizing conditions, a final etch step using a substantially oxygen-free solution of aqueous hydrofluoric acid (HF) is done. Additionally, any further processing, such as transferring the particles for storage, is done so as to maintain the nanoparticles in substantially oxygen-free conditions. For example, the hydrogen-terminated Group IV nanoparticles so formed may be transferred to an inert, substantially oxygen-free environment.

It is contemplated that plasma phase methods for producing Group IV semiconductor nanoparticles produce Group IV semiconductor nanoparticles of the quality suitable for use in making embodiments of disclosed Group IV semiconductor thin films. Such a plasma phase method, in which the particles are formed in an inert, substantially oxygen-free environment, is disclosed in U.S. patent application Ser. No. 11/155,340, filed Jun. 17, 2005; the entirety of which is incorporated herein by reference.

In reference to step 120 of process flow chart 100 shown in FIG. 1, once Group IV semiconductor nanoparticles having a desired size and size distribution have been formed in an inert, substantially oxygen-free environment, they are transferred to an inert, substantially oxygen-free dispersion solvent or solution for the preparation of embodiments dispersions and suspensions of the nanoparticles; or preparation of an ink. The transfer may take place under vacuum or under an inert, substantially oxygen-free environment. The solvents and solutions are prepared as anhydrous, for example using desiccants such as zeolites, and deoxygenated for example by sparging or freezing followed by pumping the headspace. As will be discussed in more detail subsequently, it is contemplated that one embodiment for the deposition of the dispersion of Group IV nanoparticles on a substrate is printing. In that regard, in a broad definition of an ink defined as a fluid used for printing, the dispersions of Group IV nanoparticles are in that context referred to as inks.

As those of ordinary skill in the art are aware, inks used in more traditional applications, such as graphics, are complex solutions having additives that may include numerous organic species, such as viscosity enhancers, anionic binders, and antifoaming agents. However, for the formation of an native Group IV thin film, the use of such organic additives is contraindicated, since they are frequently not volatile, and moreover at the temperatures contemplated for sintering, may decompose, or carbonize, rendering an native Group IV semiconductor thin film contaminated thereby.

Further, nanoparticles are often dispersed in solvents using surface passivation of the nanoparticles; most typically with an organic ligand that is bonded in some fashion (e.g., covalent, ionic, dipole-dipole, and the like) to atoms at the surface of the material. In the case of Group IV semiconductor nanoparticles, such surface passivation is often done using an insertion reaction with alkenes and alkynes, such as octene, octyne, octadecene, and the like. Additionally, solvents such as alcohols, ketones, and ethers, which have been previously reported as good dispersive solvents for some nanoparticles, react with the highly reactive surface atoms of the Group IV semiconductor nanoparticles to form organic passivated surfaces. For the same reason given above for the organic additives typically used in inks, such organic passivated surfaces are contraindicated in the fabrication of native Group IV thin films.

Accordingly, there is a substantial challenge to create Group IV semiconductor nanoparticle dispersions and suspensions using only hydrogen-terminated nanoparticles and solvents or solutions that are substantially oxygen-free, and leave no organic residue in embodiments of fabricated Group IV thin films disclosed herein.

Interestingly, aromatic hydrocarbon solvents of the general formulas shown below have been found to produce suitable dispersions of Group IV nanoparticles:

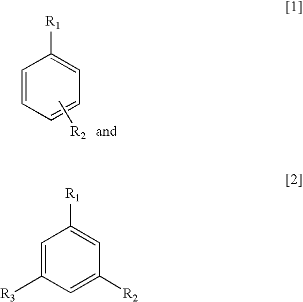

where R₁, and R₂ for solvent [1] and, R₁, R₂ and R₃ for solvent [2] are selected from short chain alkyl (C1 through C3) groups; and for solvent [1], if R₁ is selected from halogen, then R₂ is hydrogen.

Additionally, halogenated hydrocarbons (C1 and C2) have also been demonstrated to produce suitable dispersions of Group IV nanoparticles. For example, inert dispersion solvents contemplated for use include, but are not limited to chloroform, tetrachloroethane, chlorobenzene, xylenes, mesitylene, diethylbenzene, 1,3,5 triethylbenzene (1,3,5 TEB), and combinations thereof.

In terms of preparation of the dispersions, the use of particle dispersal methods such as sonication, high shear mixers, and high pressure/high shear homogenizers are contemplated for use to facilitate dispersion of the particles in a selected solvent or mixture of solvents. For example, either using a sonication bath or sonication horn has proven to be effective in producing Group IV semiconductor nanoparticle dispersions in the targeted inert oxygen-free solvents and solutions as described above. The quality of the dispersion is defined by the ability of 5 ml of dispersion to filter through a 2.5 mm diameter syringe filter of defined porosity without any significant back pressure. Observations of the filtration properties of embodiments of Group IV semiconductor nanoparticle dispersions suggests that the dispersions may have populations of colloidal particles ranging from individual particles to discrete clusters of particles of different size distributions. Typically, 2.5 mm diameter syringe filters having porosity of 0.45 micron, 1.2 micron, and 5 micron filters have been used. The ability of a dispersion to filter through a smaller pore size indicates that the dispersion has populations of smaller-sized particle clusters, which in turn is defined as a better dispersion.

For example, it has been observed that dispersions of 5 mg/ml of Group IV semiconductor nanoparticles in the inert oxygen-free solvents and solutions described in the above filter well through 1.2 micron filters. Dispersions of Group IV semiconductor nanoparticles in mesitylene and 1,3,5 TEB have at 10 mg/ml also filtered effortlessly through 1.2 micron filters. At 20 mg/ml Group IV semiconductor nanoparticles in the inert oxygen-free solvents and solutions described in the above of, none of the dispersions filtered through 1.2 micron filters. However, dispersions of nanoparticles at 20 mg/ml prepared in either mesitylene or chlorobenzene filtered through 5 micron filters.

At concentrations at or above about 10 mg/ml, solvent mixtures, or solutions, have been found to be effective for the preparation of suspensions of Group IV semiconductor nanoparticles. In such suspensions, Group IV semiconductor nanoparticles may be taken up in a 3:1 or 4:1 mixture of chloroform/chlorobenzene in a concentration range between about 10 mg/ml to about 30 mg/ml. The suspensions are sonicated in a water bath for between about 5 minutes to about 40 minutes.

As indicated from process flow chart 100 of FIG. 1, once a Group IV semiconductor nanoparticle dispersion has been prepared, then as indicated in step 130 the formation of a deposited film of particles, referred to as a porous compact, followed by the fabrication of thin film, as indicated by process step 140 can be done.

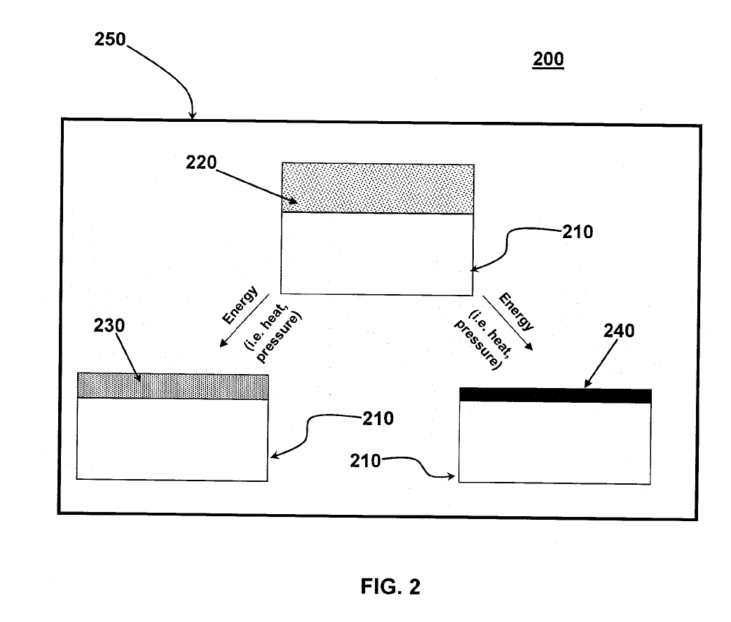

In FIG. 2, a schematic of these steps is depicted. In this schematic, a porous compact 220 is shown in a cross-sectional view, as a layer on top of a substrate 210, which may be selected from a variety of materials. For example, substrate materials may be selected from silicon dioxide-based substrates, either with or without a thin film of a material on the surface in contact with the porous compact 220. The silicon dioxide-based substrates include, but are not limited by, quartz, and glasses, such as soda lime and borosilicate glasses. The deposited thin films may be from selected from conductive materials, such as molybdenum, titanium, nickel, and platinum. Alternatively, the deposited thin films may be from selected from dielectric materials, such as silicon nitride or alumina. For some embodiments of Group IV semiconductor thin films, stainless steel is the substrate of choice. Finally, for other embodiments of Group IV semiconductor thin films, the substrate may be selected from heat-durable polymers, such as polyimides and aromatic fluorene-containing polyarylates, which are examples of polymers having glass transition temperatures above about 300° C.

From the porous compact 220, embodiments of thin films 230, 240 are fabricated in an inert environment as previously described, as indicated schematically by enclosure 250. The porous compact 220 is formed from depositing a dispersion of Group IV semiconductor nanoparticles onto a substrate 220. It is contemplated that a variety of spraying, dipping, brushing, casting, and printing technologies could be used for taking formulations of Group IV semiconductor inks and depositing a porous compact 220.

Embodiments of formulations of Group IV semiconductor inks depend on the requirements of the various deposition means, which in turn may have an impact on the characteristics of the deposited porous compact. Finally the characteristics of the thin film fabricated (e.g., 230, 240) are influenced by the deposited porous compact 220. For example, a thin porous compact with significant variation in film thickness is likely to result in a thin film having significant variation in film thickness. Therefore, the selection of a deposition technology is guided by what targeted characteristics of the deposited porous compact, and hence targeted characteristics in the final fabricated thin film. Some considerations for choosing a deposition technology include, but are not limited to, desired final thin film properties, such as thickness, surface roughness, the amount of material used, and the throughput of the deposition process.

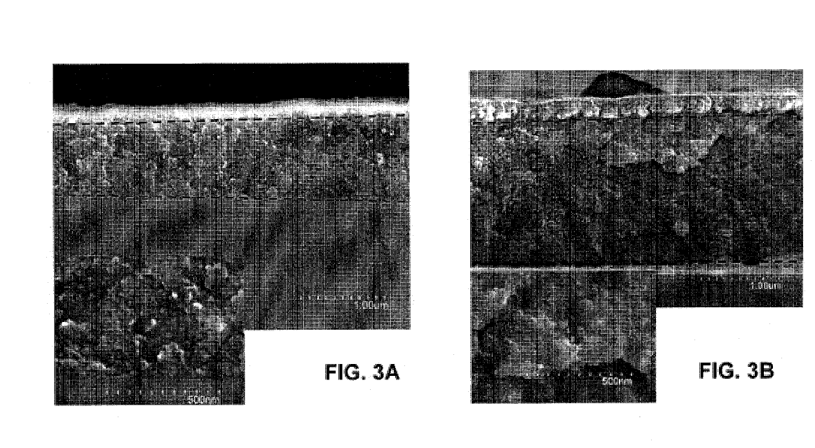

FIG. 3A and FIG. 3B show cross-sections of scanning electron micrographs (SEMs) that exemplify the impact of deposition on characteristics of porous compacts formed by comparing two different deposition methods, using formulations of silicon nanoparticles optimized for the deposition method. The substrate used in these examples, and all examples shown subsequently, is quartz. The porous compacts are delineated between the hatched lines, and shown at higher resolution in the inserts. In FIG. 3A, the cross-sectional area of a porous compact prepared from a 1 mg/ml solution of silicon nanoparticles about 8.0 nm in diameter using drop casting. As can be seen from the porous compact, which appear grainy in nature, and from the insert, which is twice the resolution, individual particles that are packed together are apparent. In FIG. 3B, a 20 mg/ml solution of silicon nanoparticles of about 8.0 nm in diameter was prepared in a solution of chloroform/chlorobenzene (4:1), and spin cast 1000 rpm for a minute. In comparison to the drop cast porous compact of FIG. 3A, the spin cast porous compact of FIG. 3B is more tightly packed, which can is more clearly visible in comparing the inserts at higher resolution.

In another aspect of what is depicted in FIG. 2, different processing conditions used in the fabrication of a thin film from a porous compact may produce characteristically different thin films. For example, in FIG. 2, a porous compact 220 under certain conditions of heat and pressure may produce a sinter 230 of more compact nature, but still having significant porosity. If the processing conditions are increased, then a densified thin film 240 is formed. In some embodiments, the processing may significantly reduce pore size, while in still other embodiments, the conditions may be selected so that pores are either greatly reduced or eliminated. Regarding pore structure, in some embodiments of sinters such as 230, the pores may be in fluid communication with other pores within the film, so that there is a network of pores through the film, and therefore in fluid communication with the external environment. As a film becomes a densified film 240, the pores may become occluded, such that they are no longer in fluid communication with other pores or the external environment. Finally, in embodiments of the most highly densified films 240, the pore structure is substantially eliminated.

With respect to the fabrication step 140 of FIG. 1, it is contemplated that processing variables impacting embodiments of Group IV semiconductor thin films include, but are not limited to the temperature, pressure, the type of inert environment used, as well as Group IV semiconductor nanoparticle properties, such as size and composition.

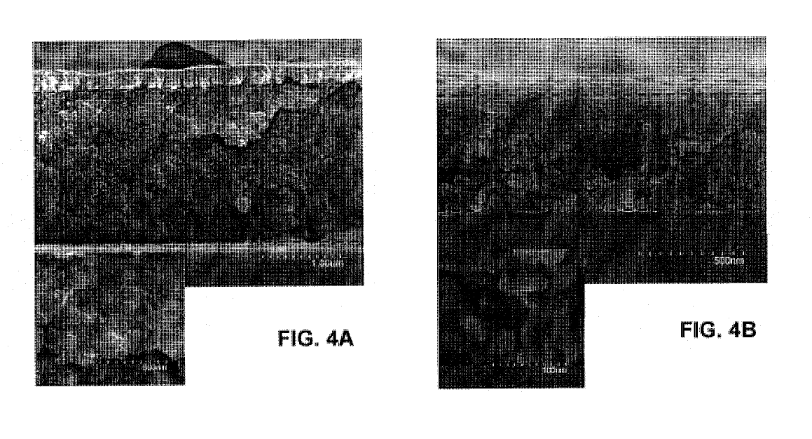

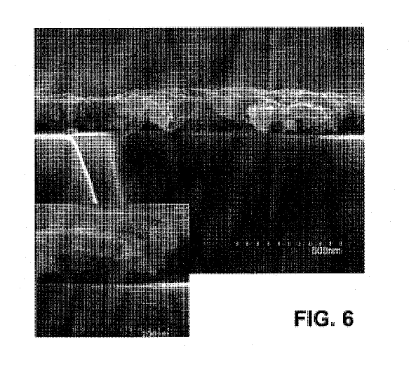

Examples of the impact of processing temperature on the formation of a Group IV semiconductor thin film from a porous compact are shown in FIGS. 4A and 4B and FIG. 6. In these figures, SEMs of the cross-sections of representative porous compacts are shown between the hatched lines in comparison to the cross-sections of embodiments of Group IV semiconductor thin films formed under different sintering temperatures.

In FIG. 4A, a porous compact shown between the hatched lines was formed from a 20 mg/ml solution of silicon nanoparticles of about 8.0 nm in diameter was prepared in a solution of chloroform/chlorobenzene (4:1), and spin cast 1000 rpm for a minute. The film produced is about 2 microns, as can be seen from the scale. In FIG. 4B embodiments of the thin film shown between the hatched lines formed from the porous compact was fabricated in vacuo at about 10⁻⁶ Torr and at temperatures between about 400° C. to about 700° C. for not more than about 15 minutes. The thin film so produced has compacted from about 2 microns to about 500 nm, or by a factor of four.

Since the behavior and properties of Group IV semiconductor nanoparticles are not thoroughly understood, terminology used for the processing of more macroscopic materials may not eventually be held to be correct when applied to such nanoparticles. In that regard, though not limited by such description, embodiments of the thin film of FIG. 4B have the appearance of a sinter, and as will be discussed in more detail subsequently, are being processed well below the melting point of bulk material. In a sinter, three major changes are noted versus a porous compact. These changes include an increase in grain size, a change in pore shape, and a change in pore size and number, generally leading to an increase in the density of a sinter. In comparison of the porous compact of FIG. 4A to the thin film of FIG. 4B, it can be seen that the grain boundaries have increased, which is more clearly seen by comparison of the inserts for FIGS. 4A and 4B, at higher resolution. That the pore size and number has changed is inferred from the compaction by a factor or four.

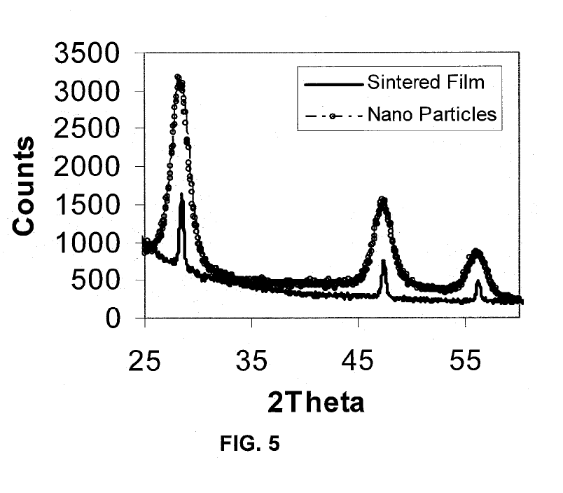

Additionally, the grain size increase can be monitored using x-ray diffraction (XRD). In FIG. 5, x-ray diffraction XRD data for an embodiment of a sintered thin film, like that of FIG. 4B, is shown in comparison to the silicon nanoparticle starting material. X-ray glancing angle measurements were performed on a Philips MRD diffractometer with copper anode source operated at 45 kV and 40 mA. The incident optics used for the measurement was an x-ray mirror to provide parallel beam, a ½° divergence slit, an automatic nickel attenuator with an attenuation factor of 171 and a 10 mm incident beam mask. The receiving optic used was a 0.27° parallel beam collimator slit and a 0.04 radians Soller slit. A glancing-angle scan with incident angle ω=1° was performed to get enough intensity. The x-ray diffraction peaks were fit using symmetric Pearson VII profile.

Qualitatively, from FIG. 5, it is noteworthy to compare the peak widths for sintered thin film in comparison to the silicon nanoparticle starting material, since the narrower band of the sintered thin film is an indication that the grain size has increased. From these data, it is possible to estimate the grain size based on Scherrer equation after deconvoluting the broadened peaks. By using this data reduction technique, it has been estimated that the grain growth is approximately at least 10 times greater for the sintered thin film than for the silicon nanoparticle starting material.

In FIG. 6, a porous compact similar to that of FIG. 4A was prepared, but was spin cast at 4000 rpm for a minute. The resulting film thickness was about 400 nm. The porous compact so formed may be processed in vacuo at about 10⁻⁶ Torr and at temperatures between about 700° C. to about 900° C. for not more than about 15 minutes to form embodiments of a densified thin film, such as that exemplified by the thin film of FIG. 6. The thin film so produced has compacted from about to about 185 nm, or by a factor of about two. In comparing the densified thin film of FIG. 6 to the sintered thin film of FIG. 4B at comparable resolution, it can be seen that the densified thin film of FIG. 6, is significantly compacted, and if pore structure exists, it is likely that such pores are highly reduced in number and size.

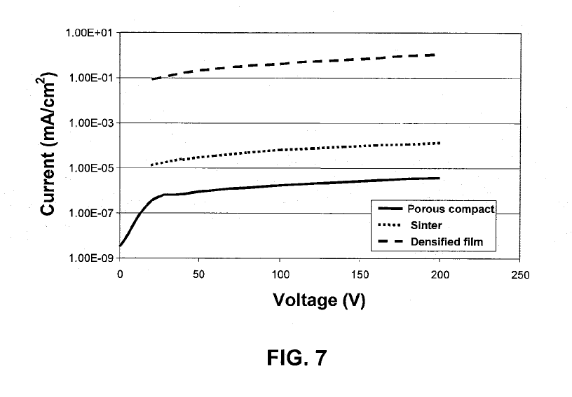

Regarding a comparison of electrical properties of the three types of thin films as discussed above, in FIG. 7, a plot of the dark current versus voltage, which is logarithmic in current, displays such a comparison. In FIG. 7, the response for a porous compact, (e.g., FIG. 3B), a sintered thin film (e.g., FIG. 4B), and a densified thin film (e.g., FIG. 6) is shown. First, it is noted that the response increases continuously over the range of applied voltage measured, which demonstrates that the films are well formed, so that there is a continuous electrical path. It is evident in from viewing the graph that the response of the porous compact is about a full decade lower in response than the sinter of FIG. 4B, and about five orders of magnitude ten less than the densified thin film of FIG. 6. The four orders of magnitude ten increase in current of the densified thin film of FIG. 6 over the thin film of FIG. 4B over the range of the voltage applied signifies that a significant change in the nature of the densified film. Additionally, absorbance spectra taken of embodiments of thin films such as those exemplified by FIG. 4B and FIG. 6 suggest that the silicon thin film formed is a mixed phase of nanocrystallite and amorphous silicon.

It should be noted that the temperatures used to form the embodiment of the sinter of FIG. 4B and embodiments of the densified thin film of FIG. 6 are significantly lower than the melting point of bulk silicon, which occurs at about 1400° C. For the embodiments of thin films contemplated having a thickness of about 150 nm to about 3 microns, such a reduction in the processing temperature enables significant advantages in the selection of substrates, as well as for the scaling of the process. For example, it is contemplated that a flexible substrate, such as stainless steel or heat-durable polymer, would be well-suited to low-temperature processes, which flexible substrates enable high-volume web processing thereby.

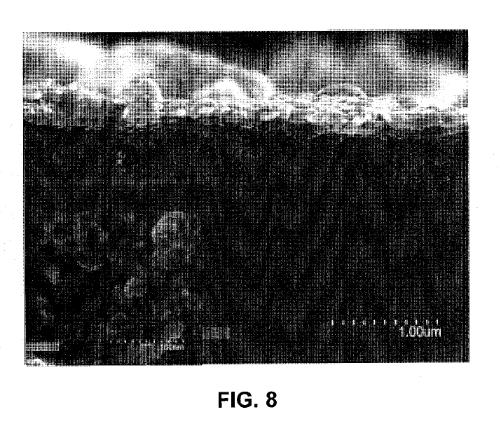

In addition to the use of temperature, the use of pressure in combination with temperature is contemplated; particularly in the range of about 3000 to about 7000 psig. In FIG. 8, a SEM showing the cross-section a porous compact prepared as shown in FIG. 4A and subjected to 7000 psig for about five minutes at room temperature. This resulted in the porous compact of initial thickness of about 2 microns to be compacted to about 500 nm in thickness, or by a factor of four, using pressure alone. For embodiments of the most densified thin films, the use of both temperature and pressure is indicated.

With respect to step 140 of FIG. 1, concerning fabricating embodiments of Group IV semiconductor thin films in an inert environment, several approaches are considered. In addition to processing in vacuo, as given in the examples above, the Group IV semiconductor thin films may be processed in inert environments using a noble gas or nitrogen, or mixtures thereof. Additionally, to create a reducing atmosphere, 20% by volume of hydrogen may be mixed with the noble gas, or nitrogen, or mixtures thereof. Though as previously discussed, “inert” is not limited in meaning to substantially oxygen free, one metric of an inert environment includes reducing the oxygen content so that the Group IV semiconductor thin films produced have no more than about 10¹⁷ to 10¹⁹ oxygen content per cubic centimeter of Group IV semiconductor thin film.

Finally, after the fabrication of the Group IV semiconductor thin film is complete, the thin film may be transferred from the inert environment, as shown in FIG. 1, step 150. After the fabrication, post-processing steps may be done, such as hydrogenation to create stable hydrogen-terminated Group IV semiconductor thin films. In such a processing step, the thin films would be subjected to a forming gas, which is a volumetric mixture of about 10% to 20% hydrogen in an inert gas, such as a noble gas of nitrogen. The processing temperature for creating hydrogen-terminated Group IV semiconductor thin films is between about 300° C. to about 350° C., for between about 0.2 to about 5 hours.

Additionally, the Group IV semiconductor nanoparticle starting material introduces variables into the fabrication of Group IV semiconductor thin films, which variables include nanoparticle size and composition. In order to introduce embodiments thin films prepared using Group IV semiconductor nanoparticles of various sizes and compositions, some perspective over the art is indicated.

In previous studies, the reduction of melting point for semiconductor nanoparticles has been the focus of theoretical, as well as experimental studies (see for example Goldstein, U.S. Pat. No. 5,576,248). In the ionic binary or higher order semiconductor nanoparticles, such as cadmium sulfide, gallium arsenide, and the like, disproportionation involving the loss of one species from a nanoparticle surface drives the melting process for of such semiconductor nanoparticles. However, this cannot explain the melting properties of the Group IV semiconductor nanoparticles, since the bonding of atoms in such nanoparticles is covalent in nature.

While the reduced melting as a function of Group IV nanoparticle diameter has been reported, it has been done so as general conjecture based on theory of ionic semiconductors, or fitted to experiments done using polydisperse Group IV nanocrystals. Such conjectures and studies focus on melting, which is a familiar property of a bulk material. Though melting is certainly a property of nanoparticle materials, given the unique properties of such materials, then unique behavior not previously reported for comparable bulk materials is likely to be discovered for this novel class of materials.

For example, the term “fusion” implies melting, the term “sintering” implies the diffusion of species across grain boundaries, and the term “agglomeration” implies formation of bonds between reactive Group IV semiconductor atoms at the surface. Given the formation of densified silicon thin films of about 200 nm to 3 microns in thickness, formed between about 400° C. to 900° C. from silicon nanoparticles of about 8 nm in diameter; it is unclear at this time what mechanisms may be involved. This is especially the case, given that the conventional wisdom for Group IV semiconductor nanoparticles holds that layers of particles greater than 3-4 particles deep would act like bulk silicon, and therefore melt at about 1400° C. For perspective, for a thin film of 150 nm to about 3 microns fabricated using Group IV nanoparticles in the range of about 1 nm and 10 nm, this would represent embodiments of Group IV semiconductor particles in excess of 15 to about 3000 nanoparticles deep, given the compaction that results in the processing of a porous compact to a thin film, as discussed previously. Though invention does not require an understanding of mechanism or theory, it is desirable to clarify the complexities that exist in the art concerning the properties of Group IV semiconductor nanoparticles, so as to highlight the uniqueness of embodiments of thin films disclosed herein.

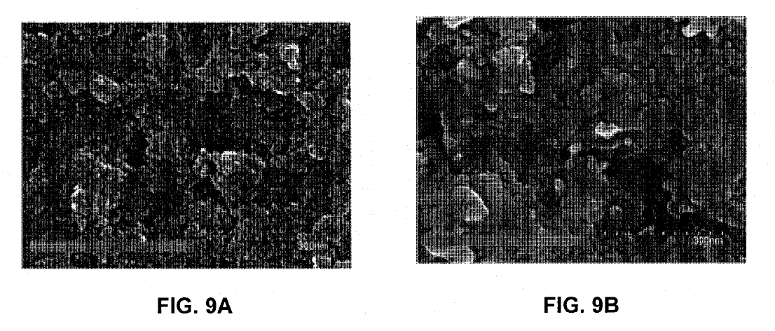

Turning attention to FIG. 9A and FIG. 9B, what is shown in these figures are plan views of germanium nanoparticles of about 4 nm prepared as a porous compact (FIG. 9A), and as a sintered thin film (FIG. 9B). The 4 nm particles were formulated as a 30 mg/ml suspension in chloroform/chlorobenzene (3:1), which was sonicated in a sonication bath for about 20 minutes. Porous compacts were prepared using spin casting at 1000 rpm for about 1 minute. Embodiments of the thin film shown in FIG. 8B were prepared from a porous compact so prepared by heating the porous compact in an inert environment at about 300° C. for up to about 15 minutes.

In comparison of the plan view of the germanium porous compact (FIG. 9A) to that of the plan view of the thin film post processing at 300° C. (FIG. 9B), it can be seen that significant growth in grain boundary has occurred in the germanium thin film. It is further evident that the germanium thin film produced at 300° C. from the germanium nanoparticles is comparable to that of silicon thin films fabricated from silicon nanoparticles at about 400° C. to about 700° C. Further, the processing temperature of 300° C. for the germanium nanoparticles is significantly below that of the melting point of bulk germanium, which is about 937° C. As such, for embodiments of Group IV semiconductor thin films utilizing germanium nanoparticles, core/shell particles containing germanium, and alloys of Group IV semiconductor nanoparticles, the processing temperature is expected to be lowered still further than for the silicon thin films fabricated from the silicon nanoparticles as previously described herein.

As will be clear to practitioners of the art, families of Group IV semiconductor thin films can be created by utilizing combinations of particle size, and particle type, in conjunction with variations of processing conditions, such as, but not limited to, temperature and pressure. For example, embodiments of thin films may be created by processing combinations of particles of the same Group IV semiconductor material of different sizes, where a certain proportion of the particles have different phase transition properties than do others. As another example, embodiments of thin films of a combination of Group IV semiconductor materials of the same or different size may be fabricated, where a certain proportion of nanoparticles having different phase transition properties than other nanoparticles are used. In still another example, embodiments of Group IV semiconductor thin films are formed from alloys or core/shell structures of silicon, germanium and alpha-tin. In some embodiments of this family, the nanoparticles created as alloys or core/shell structures may be mixed with Group IV semiconductor nanoparticles of a single material. Finally, families of Group IV semiconductor thin films may be created by selection of composition, size, and crystallinity of the nanoparticle starting material. In some embodiments of this family of thin films, in addition to composition and size as variables, particles that are amorphous in nature may be mixed with particles that are crystalline in nature.

While the principles of this invention have been described in connection with exemplary embodiments, it should be understood clearly that these descriptions are made only by way of example and are not intended to limit the scope of the invention. What has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

1.-18. (canceled)

19. A method for producing a sintered Group IV semiconductor thin film, comprising:
producing Group IV semiconductor nanoparticles in an inert environment, wherein the Group IV semiconductor nanoparticles are formed from at least one Group IV semiconductor element;
transferring the Group IV semiconductor nanoparticles to an inert liquid media in the inert environment to form a formulation of nanoparticles;
filtering the formulation of nanoparticles in the inert environment through a filter with a porosity of between about 0.45 microns and about 5.0 microns;
depositing the formulation of nanoparticles on a substrate; and
heating the substrate to a first temperature of between about 400° C. and about 900° C. for not more than about 15 minutes, wherein the sintered Group IV semiconductor thin film is formed.

20. The method of claim 19, wherein the inert liquid media comprises one of a chloroform solvent, a tetrachloroethane solvent, a chlorobenzene solvent, a xylene solvent, a mesitylene solvent, a diethylbenzene solvent, a 1,3,5 triethylbenzene (1,3,5 TEB) solvent, an alcohol solvent, a ketone solvent, and an ether solvent.

21. The method of claim 19, wherein the formulation of the Group IV semiconductor nanoparticles in the inert liquid media is between about 1 mg/ml to about 30 mg/ml.

22. The method of claim 19, wherein the filter has a porosity of about 1.2 microns to about 5.0 microns.

23. The method of claim 19, wherein the first temperature is about 700° C.

24. The method of claim 19, wherein the Group IV semiconductor nanoparticles are between about 1.0 nm and about 110 nm.

25. The method of claim 19, wherein the inert environment comprises between about 100 ppb and about 10 ppm oxygen atoms.

26. The method of claim 19, wherein the formulation of nanoparticles is an ink.

27. The method of claim 19, wherein each nanoparticle of the Group IV semiconductor nanoparticles includes an organic ligand.

28. The method of claim 19, wherein the substrate is one of a quartz substrate, a glass substrate, a stainless steel substrate, and a heat-durable polymer substrate.

29. The method of claim 19, wherein the step of heating the substrate to a first temperature of between about 400° C. and about 900° C. for not more than a first time of about 15 minutes is performed in vacuo.

30. The method of claim 19, further including the step of subjecting the sintered Group IV semiconductor thin film to a forming gas, the forming gas having a volumetric mixture of hydrogen of about 10% to about 20% in an inert gas, at a second temperature of between about 300° C. and about 350° C., and for a second time of between about 0.2 hours and about 5.0 hours, after the step of heating the substrate to a temperature of between about 400° C. and about 900° C. for not more than about 15 minutes.

31. A sintered Group IV semiconductor thin film made by a process comprising the steps of:
producing in an inert environment a set of Group IV semiconductor nanoparticles, wherein the set of Group IV semiconductor nanoparticles is formed from at least one Group IV semiconductor element;
transferring to an inert liquid media the set of Group IV semiconductor nanoparticles to form a formulation of nanoparticles;
filtering the formulation of nanoparticles through a filter with a porosity of between about 0.45 microns and about 5.0 microns;
depositing in the formulation of nanoparticles on a substrate, wherein a densified thin film is formed;
heating the substrate to a temperature of between about 400° C. and about 900° C. for not more than about 15 minutes, wherein the sintered Group IV semiconductor thin film is formed.

32. The sintered Group IV semiconductor thin film of claim 31, wherein the inert liquid media comprises one of a chloroform solvent, a tetrachloroethane solvent, a chlorobenzene solvent, a xylene solvent, a mesitylene solvent, a diethylbenzene solvent, a 1,3,5 triethylbenzene solvent, an alcohol solvent, a ketone solvent, and an ether solvent.

33. The sintered Group IV semiconductor thin film of claim 31, wherein the formulation of the Group IV semiconductor nanoparticles in the inert liquid media is between about 1 mg/ml to about 30 mg/ml.

34. The sintered Group IV semiconductor thin film of claim 31, wherein the filter has a porosity of about 1.2 microns to about 5.0 microns.

35. The sintered Group IV semiconductor thin film of claim 31, wherein the temperature is about 700° C.

36. The sintered Group IV semiconductor thin film of claim 31, wherein the Group IV semiconductor nanoparticles are between about 1.0 nm and about 100 nm.

37. The sintered Group IV semiconductor thin film of claim 31, wherein the inert environment comprises between about 100 ppb and about 10 ppm oxygen atoms.

38. The sintered Group IV semiconductor thin film of claim 31, wherein the formulation of nanoparticles is an ink.

39. The sintered Group IV semiconductor thin film of claim 31, wherein each nanoparticle of the Group IV semiconductor nanoparticles includes an organic ligand.

40. The sintered Group IV semiconductor thin film of claim 31, wherein the substrate is one of a quartz substrate, a glass substrate, a stainless steel substrate, and a heat-durable polymer substrate.

41. The sintered Group IV semiconductor thin film of claim 31, wherein the step of heating the substrate to a first temperature of between about 400° C. and about 900° C. for not more than a first time of about 15 minutes is performed in vacuo.

42. The sintered Group IV semiconductor thin film of claim 31, further including the step of subjecting the sintered Group IV semiconductor thin film to a forming gas, the forming gas having a volumetric mixture of hydrogen of about 10% to about 20% in an inert gas, at a second temperature of between about 300° C. and about 350° C., and for a second time of between about 0.2 hours and about 5.0 hours, after the step of heating the substrate to a temperature of between about 400° C. and about 900° C. for not more than about 15 minutes.

43. A sintered Group IV semiconductor thin film made by a process comprising the steps of:
producing in an inert environment a set of Group IV semiconductor nanoparticles, wherein the set of Group IV semiconductor nanoparticles includes a set of germanium nanoparticles;
transferring to an inert liquid media the set of Group IV semiconductor nanoparticles to form a formulation of nanoparticles;
filtering the formulation of nanoparticles through a filter with a porosity of between about 0.45 microns and about 5.0 microns;
depositing in the formulation of nanoparticles on a substrate, wherein a densified thin film is formed;
heating the substrate to a temperature of between about 300° C. and for not more than about 15 minutes, wherein a sintered Group IV semiconductor thin film is formed.

44. The sintered Group IV semiconductor thin film of claim 43, wherein the inert liquid media comprises one of a chloroform solvent, a tetrachloroethane solvent, a chlorobenzene solvent, a xylene solvent, a mesitylene solvent, a diethylbenzene solvent, a 1,3,5 triethylbenzene solvent, an alcohol solvent, a ketone solvent, and an ether solvent.

45. The sintered Group IV semiconductor thin film of claim 43, wherein the formulation of the Group IV semiconductor nanoparticles in the inert liquid media is between about 1 mg/ml to about 30 mg/ml.

46. The sintered Group IV semiconductor thin film of claim 43, wherein the filter has a porosity of about 1.2 microns to about 5.0 microns.

47. The sintered Group IV semiconductor thin film of claim 43, wherein the Group IV semiconductor nanoparticles are between about 1.0 nm and about 100 nm.

48. The sintered Group IV semiconductor thin film of claim 43, wherein the inert environment comprises between about 100 ppb and about 10 ppm oxygen atoms.

49. The sintered Group IV semiconductor thin film of claim 43, wherein the formulation of nanoparticles is an ink.

50. The sintered Group IV semiconductor thin film of claim 43, wherein each nanoparticle of the Group IV semiconductor nanoparticles includes an organic ligand.

51. The sintered Group IV semiconductor thin film of claim 43, wherein the substrate is one of a quartz substrate, a glass substrate, a stainless steel substrate, and a heat-durable polymer substrate.

52. The sintered Group IV semiconductor thin film of claim 43, wherein the step of heating the substrate to a first temperature of between about 400° C. and about 900° C. for not more than a first time of about 15 minutes is performed in vacuo.

53. The sintered Group IV semiconductor thin film of claim 43, further including the step of subjecting the sintered Group IV semiconductor thin film to a forming gas, the forming gas having a volumetric mixture of hydrogen of about 10% to about 20% in an inert gas, at a second temperature of between about 300° C. and about 350° C., and for a second time of between about 0.2 hours and about 5.0 hours, after the step of heating the substrate to a temperature of between about 400° C. and about 900° C. for not more than about 15 minutes.
